(19) United States
(12) Patent Application Publication
(10) Pub. No.: US 2021/0265205 A1
(43) Pub. Date: Aug. 26, 2021

(54) DIELECTRIC ETCH STOP LAYER FOR REACTIVE ION ETCH (RIE) LAG REDUCTION AND CHAMFER CORNER PROTECTION

(71) Applicant: Tokyo Electron Limited, Tokyo (JP)

(72) Inventors: Yen-Tien Lu, Albany, NY (US); Xinghua Sun, Albany, NY (US); Michael Edley, Albany, NY (US); Angelique Raley, Albany, NY (US)

(21) Appl. No.: 17/179,117

(22) Filed: Feb. 18, 2021

Related U.S. Application Data
(60) Provisional application No. 62/981,144, filed on Feb. 25, 2020.

(51) Int. Cl. H01L 21/768

(52) U.S. Cl. CPC H01L 21/76831; H01L 21/76832

(57) ABSTRACT

Stacked structures, process steps, and methods for via and trench formation use a dielectric etch stop layer (ESL) to reduce or eliminate problems, such as process lag and chamfer erosion, that occur during conventional etch processes. A stacked structure is formed that includes a dielectric ESL within a dielectric layer, such as a low-dielectric (low-K) layer, to form a first low-K layer below the dielectric ESL and a second low-K dielectric layer above the dielectric ESL. When the stacked structure is subsequently etched to form trenches as well as vias through the stacked structure to underlying layers, the dielectric ESL reduces or eliminates RIE lag by ensuring that trenches (regardless of width) stop on the dielectric ESL. The dielectric ESL also acts as a protective layer to protect corners from chamfer erosion during via and trench etch processes.

This application claims priority to U.S. Provisional Patent Application No. 62/981,144, entitled, “DIELECTRIC ETCH STOP LAYER FOR REACTIVE ION ETCH (ME) LAG REDUCTION AND CHAMFER CORNER PROTECTION,” filed Feb. 25, 2020; the disclosure of which is expressly incorporated herein, in its entirety, by reference.

### BACKGROUND

The present disclosure relates to methods for the manufacture of microelectronic workpieces including the formation of patterned structures, such as vias, lines and trenches, on microelectronic workpieces.

Device formation within microelectronic workpieces typically involves a series of manufacturing techniques related to the formation, patterning, and removal of layers of material on a substrate. To meet the physical and electrical specifications of current and next generation semiconductor devices, process flows are being requested to reduce feature size while maintaining structure integrity for various patterning processes.

As part of one conventional process, vias and trenches are formed within a stacked structure. The stacked structure can include an organic layer and one or more hard mask layers formed over a dielectric layer. For this conventional process, various etch processes are performed to form the vias and trenches in the stacked structure. However, as described below with respect to FIGS. 1A-1F (Prior Art) and FIG. 2 (Prior Art), certain problems are experienced with respect to this conventional process.

FIGS. 1A-1F (Prior art) provide cross-section views of example embodiments for conventional etch processes that may be used to form self-aligned vias and related trenches within a stacked structure. It is noted that these cross-section views are in a first direction perpendicular to trenches being formed in the stacked structure and show multiple vias being formed within the stacked structure. For this example back-end-of-line (BEOL) process, the stacked structure includes an organic layer, such as an organic planarization layer (OPL) layer, one or more hard mask (HM) layers, and a low-dielectric-constant (low-K) layer and an etch stop layer (ESL) formed over a neighbor interlayer dielectric (ILD) layer containing metal regions. Etch processes are subsequently performed to form vias and trenches within the stacked structure.

Unfortunately, problems often occur during the etch processes. For example, where trenches of different widths are formed and/or where reactive ion etch (RIE) processes are used, RIE lag or aspect-ratio-dependent etching (ARDE) may occur and cause undesirable variations in the resulting structures. In addition, erosion of pattern corners may occur during the etch processes, for example, due to sputtering of the softer materials typically used for low-K layer. Both problems can lead to short circuits or other problems thereby degrading performance for devices being formed on microelectronic workpieces.

Looking now to FIG. 1A (Prior Art), a cross-section diagram is provided of an example embodiment 100 for a stacked structure formed on a substrate for a microelectronic workpiece. In the embodiment 100 shown in FIG. 1A (Prior Art), metal regions 104 are formed within an interlayer dielectric (ILD) layer 102. An etch stop layer (ESL) 106, such as a barrier low dielectric (k) (Blok) layer, and a low-K layer 108 are formed over the metal regions 104 and ILD layer 102. Next, a plurality of hard mask (HM) layers 110 are formed over the low-K layer 108, and an organic layer 112, such as an OPL layer, is formed over the hard mask layers 110. The HM layers 110 can include, for example, a first hard mask layer (HM1), a metal hard mask (Metal HM) layer, and a second hard mask layer (HM2). Further, for the example embodiment 100, a trench opening 115 has been formed within the first hard mask layer (HM1) and the metal HM layer. Although not shown in FIG. 1A (Prior Art), one or more additional layers (such as a photoresist layer) may be formed above the organic layer 112 and patterned with a via pattern so that vias may be formed within the stacked structure. As described in FIGS. 1B-1F (Prior Art), the stacked structure shown in FIG. 1A (Prior Art) may be processed to form vias and trenches within the stacked structure.

FIG. 1B (Prior Art) is a cross-section diagram of an example embodiment 120 after an etch process has been performed to form vias 114 through the organic layer 112, hard mask layers 110, and partially into the low-K layer 108. The etch process can be implemented, for example, as one or more plasma etch process steps, although other etch processes could also be used.

FIG. 1C (Prior Art) is a cross-section diagram of an example embodiment 130 after an etch process has been performed to extend the vias 114 through the low-K layer 108 to the ESL 106. The etch process can be implemented, for example, as one or more plasma etch process steps, although other etch processes could also be used.

FIG. 1D (Prior Art) is a cross-section diagram of an example embodiment 140 after an ash process has been performed to remove the organic layer 112 from an upper surface of the stacked structure.

FIG. 1E (Prior Art) is a cross-section diagram of an example embodiment 150 after an etch process has been performed to remove exposed portions of the hard mask layers 110, which include partial removal of HM1 and HM2 layers. The etch process also forms recesses in the ESL 106 within the vias 114. The etch process can be implemented, for example, as one or more plasma etch process steps, although other etch processes could also be used.

FIG. 1F (Prior Art) is a cross-section diagram of an example embodiment 160 after a trench etch process has been performed to etch the low-k layer 108 within the trench opening 115, as represented by arrow 162. The trench etch process also extends the vias 114 through the ESL 106 to the metal regions 104. The etch process shown in FIG. 1F (Prior Art) can be implemented, for example, using one or more RIE processes, although other etch processes could also be used. During the trench etch, corners adjacent the vias 114 are often eroded, for example, due to sputtering of the softer material used within the low-K layer 108. These eroded corners are call chamfers. Example chamfers 164 are shown in FIG. 1F (Prior Art). In addition, RIE lag or ARDE often occur where trenches have different widths.

FIG. 2 (Prior Art) provides a different cross-section diagram of an example embodiment 200 associated with resulting structures in FIG. 1F (Prior Art) where different sized trenches have been formed. In contrast to FIG. 1F (Prior Art), embodiment 200 provides a cross-section view in a second direction parallel with trenches formed in the stacked structure, and this view does not pass through vias formed within the stacked structure. For the example embodiment 200, three trenches 182, 184, and 186 are shown with differing widths (e.g., W1, W2, W3). Before the low-K layer 108 is etched, via 182 will have a higher aspect ratio as compared to the wider vias 184 and 186, and the trench 184 will have a higher aspect ratio as compared to via 186. Due to RIE lag and/or ARDE, trenches with higher aspect ratios are typically etched at a slower rate than trenches with lower aspect ratios. This results in non-uniform depth of the trenches 182, 184, and 186 after the trench etch of the low-K layer 108. For example, trench 184 and trench 186 differ by depth 188; trench 182 and via 186 differ by depth 190; and trench 182 and trench 184 differ by depth 192. These non-uniform depths lead to short circuits and/or other problems in resulting structures that degrade performance for the devices being formed on the microelectronic workpiece.

### SUMMARY

Various embodiments of stacked structures, process steps, and methods for via/trench formation are provided herein to reduce or eliminate problems, such as RIE lag and chamfer erosion, that occur during conventional etch processes. As described herein, a stacked structure is formed that includes a dielectric etch stop layer (ESL) formed within a dielectric layer, such as a low-K layer, to provide a first low-K layer below the dielectric ESL and a second low-K dielectric layer above the dielectric ESL. When the stacked structure is subsequently etched to form trenches as well as vias through the stacked structure, the dielectric ESL reduces or eliminates RIE lag by ensuring that trenches (regardless of width) stop on the dielectric ESL. The dielectric ESL also acts as a protective layer to protect corners from chamfer erosion during via and trench etch processes. Other advantages and implementations can also be achieved while still taking advantage of the process techniques described herein.

For one embodiment, a method for via and trench formation is disclosed including forming a stacked structure on a substrate for a microelectronic workpiece where the stacked structure includes a dielectric etch stop layer (ESL) formed between a first low-dielectric-constant (low-K) layer and a second low-K layer, forming at least one additional layer above the stacked structure, performing one or more etch processes to form vias within the stacked structure that extend through the second low-K layer and the dielectric ESL and the first low-K layer, and performing one or more trench etch processes to etch the second low-K layer while using the dielectric ESL as an etch stop for the one or more trench etch processes.

In additional embodiments, the one or more trench etch processes includes a reactive ion etch (RIE) process. In further embodiments, the dielectric ESL helps to reduce RIE lag associated with the RIE process as compared to process steps that do not use the dielectric ESL.

In additional embodiments, the dielectric ESL is formed within the stacked structure at a target trench depth. In further additional embodiments, a plurality of trenches are formed with different widths, and a common depth is achieved for the trenches during the one or more trench etch processes based upon the dielectric ESL.

In additional embodiments, the dielectric ESL protects corners of structures adjacent to the vias during the one or more trench etch processes. In further embodiments, chamfer profiles for the corners are controlled by using the dielectric ESL.

In additional embodiments, the dielectric ESL is formed within the stacked structure by depositing the dielectric ESL onto the first low-K layer. In further embodiments, the dielectric ESL has a thickness of less than 20 nanometers. In other further embodiments, the dielectric ESL has a thickness of 1 to 3 nanometers. In other further embodiments, the depositing the dielectric ESL on the first low-K layer includes an atomic layer deposition (ALD) process.

In additional embodiments, the dielectric ESL includes at least one of AlO, AlN, SiC, SiCN, SiNCH, SiO₂, SiN, or SiON. In further additional embodiments, the first low-K layer and the second low-K layer include at least one of SiCOH or SiNCH.

In additional embodiments, the one or more trench etch processes have an etch rate (R_{LOW-K}) for the second low-K layer that is four (4) times to twenty (20) times more than an etch rate (R_{ESL}) for the dielectric ESL such that 4≤R_{LOW-K}/R_{ESL}≤20.

In additional embodiments, the at least one additional layer includes one or more hard mask layers formed over the second low-K layer and an organic layer formed over the one or more hard mask layers.

For one embodiment, a method for via and trench formation is disclosed including forming metal regions within a layer on a substrate for a microelectronic workpiece, forming an etch stop layer (ESL) over the metal regions, forming a first low-dielectric-constant (low-K) layer over the ESL, forming a dielectric ESL over the first low-K layer, forming a second low-K layer over the dielectric ESL, forming one or more additional layers over the second low-K layer, performing one or more etch processes to form vias that extend through the second low-K layer and the dielectric ESL and the first low-K layer, and performing one or more trench etch processes including a reactive ion etch (RIE) process to etch the second low-K layer while using the dielectric ESL as an etch stop for the one or more trench etch processes.

In additional embodiments, the dielectric ESL helps to reduce RIE lag associated with the RIE process as compared to process steps that do not use the dielectric ESL.

In additional embodiments, a plurality of trenches are formed with different widths, and a common depth is achieved for the trenches during the one or more trench etch processes based upon the dielectric ESL.

In additional embodiments, the dielectric ESL protects corners of structures adjacent to the vias during the performing of the one or more trench etch processes, and chamfer profiles for the corners are controlled by using the dielectric ESL.

In additional embodiments, the one or more trench etch processes have an etch rate (R_{LOW-K}) for the second low-K layer that is four (4) times to twenty (20) times more than an etch rate (R_{ESL}) for the dielectric ESL such that 4≤R_{LOW-K}/R_{ESL}≤20.

Different or additional features, variations, and embodiments can also be implemented, and related systems and methods can be utilized as well.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIGS. 1A-1F (Prior Art) provide cross-section views along a first direction of example embodiments for conventional process steps to form vias and trenches within a stacked structure.

FIG. 2 (Prior Art) provides a cross-section view along a second direction showing trench depth variations that often occur during the conventional process steps shown in FIGS. 1A-1F (Prior Art).

FIGS. 3A-3K provide cross-section views along a first direction of example embodiments for process steps to form vias and trenches within a stacked structure using an additional dielectric ESL to reduce or eliminate process lag and chamfer erosion during via/trench formation.

FIG. 4 provides a cross-section view along a second direction of common trench depths achieved using the techniques according to the process steps of FIGS. 3A-3K

FIG. 5 is a flowchart diagram illustrating one embodiment of a method for via and trench formation according to the techniques described herein.

### DETAILED DESCRIPTION

Various embodiments of stacked structures, process steps and methods for via and trench formation are provided herein to reduce or eliminate problems, such as RIE lag and chamfer erosion, that occur during conventional etch processes. As described herein, a stacked structure is formed that includes a dielectric etch stop layer (ESL) within a dielectric layer, such as a low-K layer, to form a first low-K layer below the dielectric ESL and a second low-K dielectric layer above the dielectric ESL. When the stacked structure is subsequently etched to form trenches as well as vias through the stacked structure, the dielectric ESL reduces or eliminates RIE lag by ensuring that trenches (regardless of width) stop on the dielectric ESL. The dielectric ESL also acts as a protective layer to protect corners from chamfer erosion during via and trench etch processes. Other advantages and implementations can also be achieved while still taking advantage of the process techniques described herein.

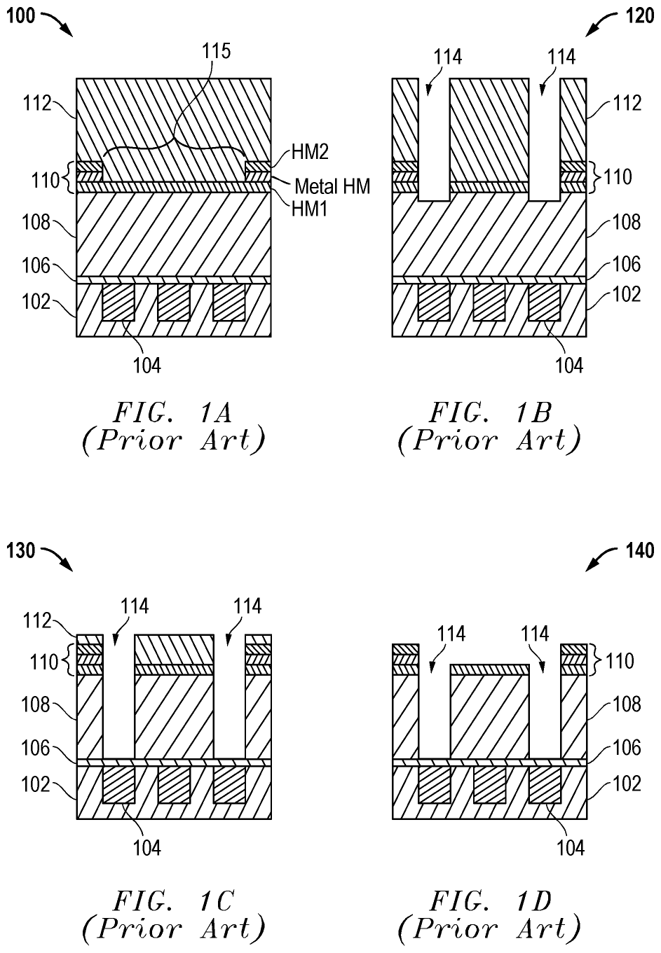

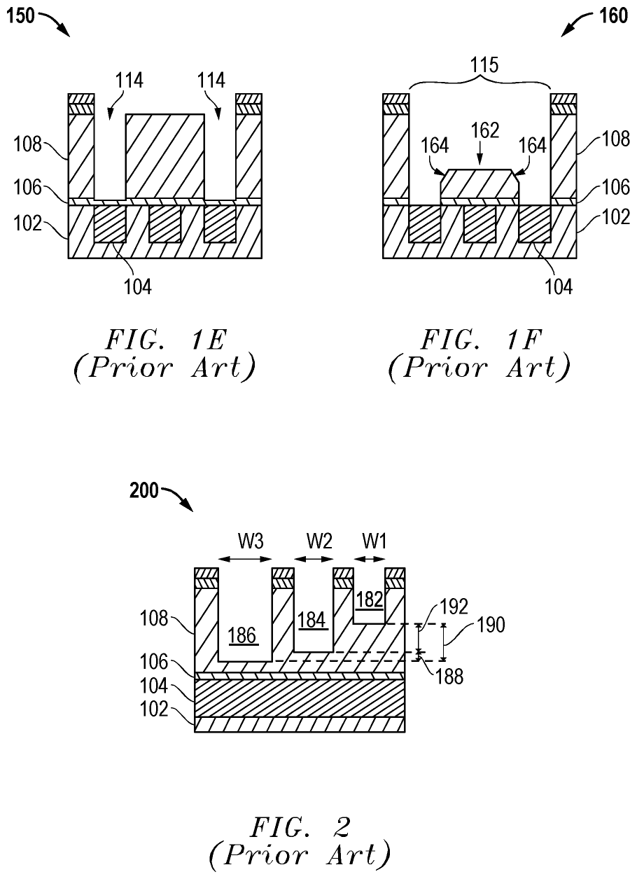

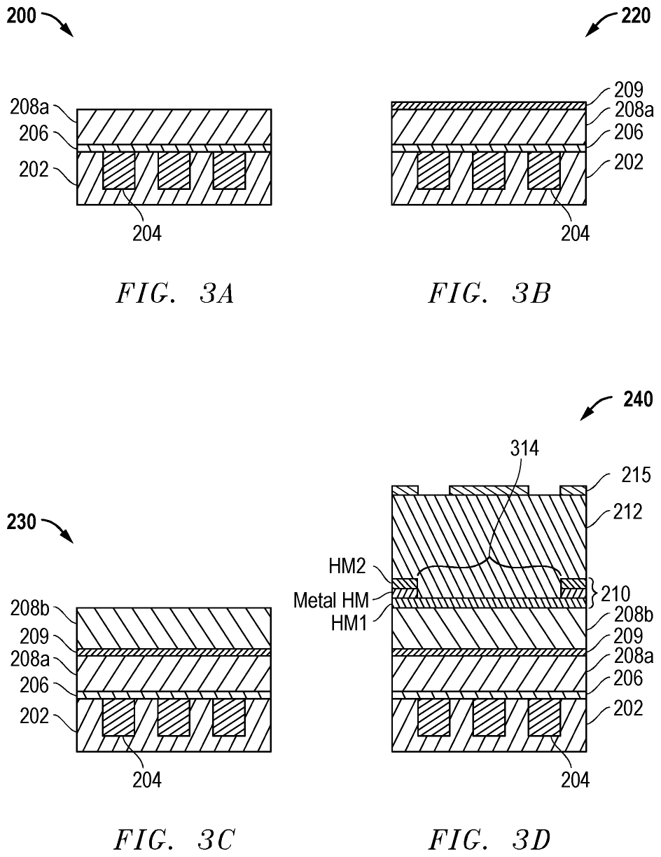

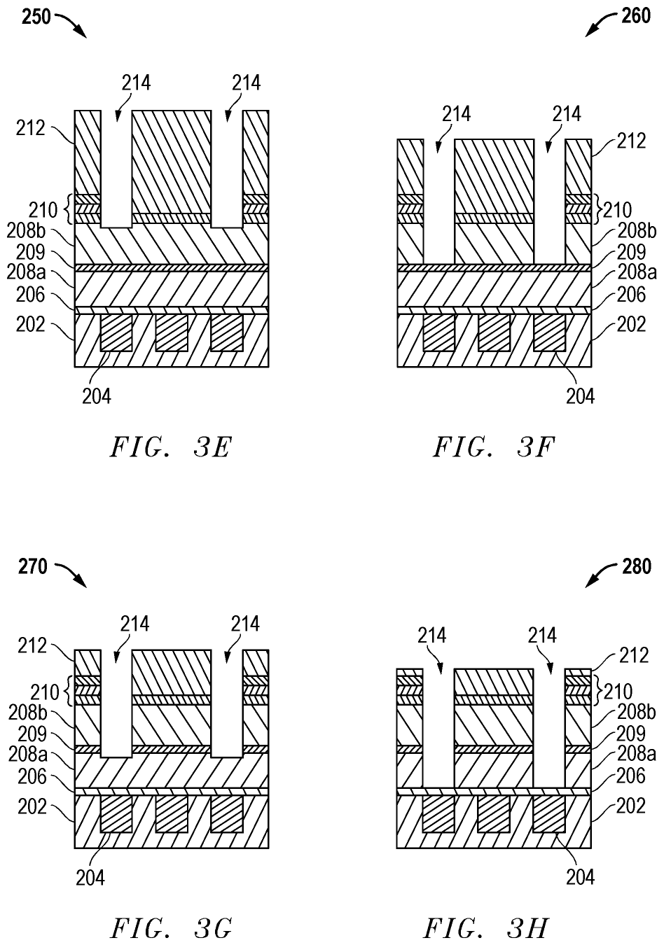

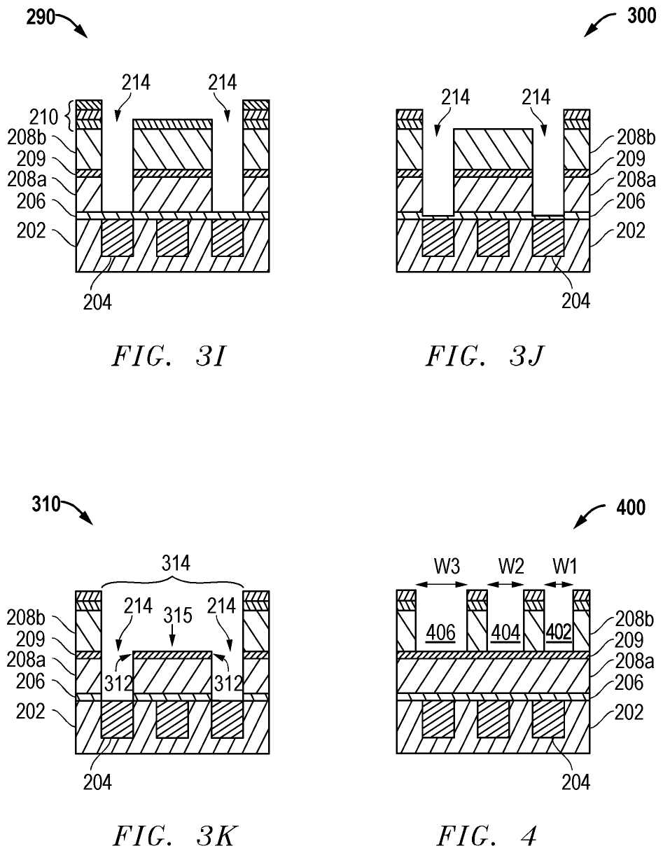

FIGS. 3A-3K provide cross-section views of example embodiments for stacked structures and process steps that reduce or eliminate problems, such as trench depth variability and chamfer erosion, suffered in prior solutions. It is noted that these cross-section views are in a first direction perpendicular to trenches being formed in the stacked structure and show multiple vias being formed within the stacked structure. The process steps can be part of a BEOL process where stacked structures are opened for via and trench formation to provide contact paths to underlying conductive layers. For the disclosed embodiments, the stacked structure is formed such that a dielectric ESL is positioned between a first low-K layer and a second low-K layer. Further, these layers can be formed over underlying layers, such as an interlayer dielectric (ILD) layer containing metal contact regions. Unlike the conventional stacked structure shown in FIGS. 1A-1F (Prior Art), the dielectric ESL included within the stacked structure shown in FIGS. 3A-3K helps to reduce chamfer erosion and to achieve uniform trench depth regardless of trench width and aspect ratios. In part, problems associated with RIE lag and/or chamfer erosion that occur during conventional process steps are reduced or eliminated. Other advantages can also be achieved and process variations can be implemented while still taking advantage of the techniques described herein.

FIG. 3A is cross-section diagram of an example embodiment 200 where a stacked structure has been formed including a first low-K dielectric layer 208a formed over one or more underlying layers. For the example embodiment in FIG. 3A, metal regions 204 have been formed and are included within an interlayer dielectric (ILD) layer 202 formed on a substrate for a microelectronic workpiece. The ILD layer 202 may be oxide (e.g., SiO₂), silicon nitride (e.g., Si₃N₄), and/or other dielectric materials or combinations of materials. Metal regions 204 may include copper and/or other metal materials or combinations of materials. For the example embodiment 200, an etch stop layer (ESL) 206, such as a barrier low dielectric (k) (Blok) layer, is also formed over the metal regions 204 and the underlying ILD layer 202. The first low-K layer 208a can be, for example, a layer of SiCOH, a layer of SiNCH, and/or a layer of another selected low-K material or combination of materials. The ESL 206 can be, for example, SiCN, SiC, AlO, SiOC, SiOCN, and/or other dielectric barrier materials or combinations of materials. These layers can be formed, for example, using one or more deposition processes including an atomic layer deposition (ALD), a chemical vapor deposition (CVD) process, a plasma deposition process, or other deposition processes or combinations of processes.

FIG. 3B is a cross-section diagram of an example embodiment 220 after a dielectric ESL 209 has been formed on the first low-K layer 208a to provide an etch stop for the subsequent trench etch process in FIG. 3F below. The dielectric ESL 209 may include a wide variety of dielectric materials such as, but not limited to, aluminum oxide (AlO), aluminum nitride (AlN), silicon carbide (SiC), silicon carbonitride (SiCN), silicon carbon oxide (SiOC), hydrogen doped silicon nitride carbide (SiNCH), silicon dioxide (SiO₂), silicon nitride (SiN), silicon oxynitride (SiON), and/or other dielectric materials or combinations of materials. The dielectric ESL 209 is preferably a material having a much slower etch rate than the material used for the first low-K layer 208a and the second low-K layer 208b described with respect to FIG. 3C below. Regardless of the particular material chosen, for example, the dielectric ESL 209 preferably has different etch characteristics (e.g., etch rate, etch selectivity, etc.) than the first low-K layer 208a and the second low-K layer 208b. These different etch characteristics allow the dielectric ESL 209 to act as an etch stop during a subsequent etch processes, such as shown in FIG. 3F, and to protect underlying portions of the first low-K layer 208a.

The dielectric ESL 209 may be deposited onto the first low-K layer 208a using chemical vapor deposition (CVD), plasma enhanced CVD (PECVD), physical vapor deposition (PVD), atomic layer deposition (ALD), and/or other deposition processes or combinations of processes. In one embodiment, ALD may be used to deposit a relatively thin dielectric ESL 209 onto the first low-K layer 208a. In some embodiments, the dielectric ESL 209 may be deposited to a thickness of less than 20 nanometers (nm), a thickness of less than 10 nm, or a thickness of less than 5 nm. In one example embodiment, ALD may be used to deposit the dielectric ESL 209 to a thickness of 1-3 nm. Other variations can also be implemented.

In some embodiments, the dielectric ESL 209 may be formed at a target trench depth within the stacked structure. By including dielectric ESL 209 within the stacked structure, different trenches (e.g., trenches of different widths and sizes) can be formed in common etch process steps while achieving a common target trench depth based upon the placement of the dielectric ESL 209. An example for this result is described with respect to FIG. 4 below. Other advantages can also be achieved while still taking advantage of the techniques described herein.

FIG. 3C is a cross-section view of an example embodiment 230 after a second low-K layer 208b is formed on the dielectric ESL 209. As with the first low-K layer 208a, the second low-K layer 208b can be, for example, a layer of SiCOH, a layer of SiNCH, and/or a layer of another selected low-K material or combination of materials. In some embodiments, the first low-K layer 208a and the second low-K layer 208b may be formed from the same dielectric material. In other embodiments, the first low-K layer 208a and the second low-K layer 208b may be formed from different dielectric materials. The second low-K layer 208b can be formed, for example, using one or more deposition processes including an atomic layer deposition (ALD), a chemical vapor deposition (CVD) process, a plasma deposition process, or other deposition processes or combinations of processes.

FIG. 3D is cross-section view of an example embodiment 240 where additional layers for a stacked structure have been formed over the second low-K layer 208b. For the example embodiment in FIG. 3D, the additional layers include hard mask (HM) layers 210, an organic layer 212, and a patterned mask layer 215. The patterned mask layer 215 can be a photoresist (PR) layer that has been patterned for via formation. The HM layers 210 can be, for example, a first hard mask layer (HM1), a metal hard mask (HM) layer, and a second hard mask layer (HM2). Further, for the example embodiment 240, a trench opening 314 has been formed within the first hard mask layer (HM1) and the metal HM layer. The organic layer 212 can be an organic planarization layer (OPL) layer, a spin-on carbon (SoC) layer, and/or a layer of another selected organic material or combination of materials. The first hard mask (HM1) layer and the second hard mask (HM2) layer may each include a variety of masking materials and/or layers such as, but not limited to, SiN, SiO, SiON, and/or other hard mask materials. The metal hard mask (Metal HM) layer may include, for example, TiN, TiO, other metals or metal oxides, and/or other metal materials or combinations of materials. These layers can be formed, for example, using one or more deposition processes including an atomic layer deposition (ALD), a chemical vapor deposition (CVD) process, a plasma deposition process, or other deposition processes or combinations of processes.

Looking now to FIGS. 3E-3K, cross-section diagrams are provided that illustrate example embodiments of process steps that may be performed to form trenches as well as vias within the stacked structure shown in FIG. 3D. As noted above, the stacked structure shown in FIG. 3D improves upon the conventional stacked structure shown in FIG. 1A (Prior Art) by including a dielectric ESL 209 between the first low-K layer 208a and the second low-K layer 208b. As described further below, the dielectric ESL 209 helps to reduce problems associated with prior solutions and helps to achieve common trench depths. In particular, common trench etch processes can be used across different sized trenches, and the dielectric ESL 209 will provide a common etch stop for the trenches. Problems caused by RIE lag in conventional etch processes are thereby reduced, and chamfer erosion is also reduced or eliminated by the dielectric ESL 209 during these trench etch processes.

FIG. 3E is a cross-section diagram of an example embodiment 250 after an etch process has been performed to open the vias 214 through the organic layer 212, the hard mask layers 210, and partially into the second low-K layer 208b. The etch process can be implemented, for example, as one or more plasma etch process steps, although other etch processes could also be used.

FIG. 3F is a cross-section diagram of an example embodiment 260 after an etch process has been performed to extend the vias 214 through the second low-K layer 208b to the dielectric ESL 209. The etch process shown in FIG. 3F can be implemented, for example, as one or more plasma etch process steps. In some embodiments, one or more etch processes used to etch the second low-K layer 208b have a higher selectivity to the dielectric ESL 209 than to the second low-K layer 208b. For example, the etch rate (R_{LOW-K}) for the second low-K layer 208b can be four (4) times to twenty (20) times the etch rate (R_{ESL}) for the dielectric ESL 209 (e.g., 4≤R_{LOW-K}/R_{ESL}≤20). This selectively helps to ensure that the etch process, such as a plasma etch process, for the second low-K layer 208b stops on the dielectric ESL 209.

FIG. 3G is a cross-section diagram of an example embodiment 270 after an etch process has been performed to extend the vias 214 through the dielectric ESL 209 and into the first low-K layer 208a. The etch process shown in FIG. 3G can be implemented, for example, as one or more plasma etch process steps, although other etch processes and combinations of processes can be used. In some embodiments, the etch recipe used to perform this etch process may have a higher selectivity to the second low-K layer 208b than the dielectric ESL 209.

FIG. 3H is a cross-section diagram of an example embodiment 280 after an etch process has been performed to extend the vias 214 through the first low-K layer 208a to the ESL 206. This etch process shown in FIG. 3H can be implemented, for example, as one or more plasma etch process steps. In some embodiments, the etch recipe used to perform this etch process may have a high selectivity to the ESL 206 to help to ensure that the plasma etch process stops on the ESL 206. In addition, the etch recipe used to perform the etch process may also have a high selectivity to the dielectric ESL 209 to avoid etching side portions of the dielectric ESL 209 during the etch process.

FIG. 3I is a cross-section diagram of an example embodiment 280 after an ash process has been performed to remove remaining portions of the organic layer 212 from the upper surface of the stacked structure.

FIG. 3J is a cross-section diagram of an example embodiment 350 after an etch process has been performed to remove exposed portions of the hard mask layers 210, which include partial removal of HM1 and HM2 layers. The etch process also forms recesses in the ESL 206 within the vias 214. The etch process can be implemented, for example, as one or more plasma etch process steps, although other etch processes could also be used.

FIG. 3K is a cross-section diagram of an example embodiment 310 after a trench etch process has been performed. This trench etch process removes the exposed portion of the second low-K layer 208b within trench opening 314 and stops on the dielectric ESL 209, as represented by arrow 315. The trench etch process also extends the vias 214 through the ESL 206 to the metal regions 204. The trench etch process shown in FIG. 3K can be implemented, for example, using one or more RIE processes, although other etch processes could also be used. As shown in FIG. 3K, the corners 312 adjacent the vias 114 are protected by the dielectric 209 during this trench etch process. As noted above, the material used for the dielectric ESL 209 may have significantly different etch characteristics (e.g., etch rate, etch selectivity, etc.) than the material used for the first low-K layer 208a. This enables the dielectric ESL 209 to protect the corners 312 that would otherwise be exposed and eroded during the trench etch. As such, chamfers and chamfer erosion is reduced or eliminated as compared to prior solutions as shown in FIG. 1F (Prior Art). Further, by protecting the corners 312 of the first low-K layer 208a that are adjacent the vias 214 during the trench etch process, chamfer profiles for the corners 312 are controlled and target chamfer angles can be achieved.

In some embodiments, the trench etch processes used to etch the second low-K layer 208b have a higher selectivity to the dielectric ESL 209 than to the second low-K layer 208b. For example, the etch rate (R_{LOW-K}) for the second low-K layer 208b can be four (4) times to twenty (20) times the etch rate (R_{ESL}) for the dielectric ESL 209 (e.g., 4≤R_{LOW-K}/R_{ESL}≤20). This selectively helps to ensure that the trench etch process, such as a plasma etch process, for the second low-K layer 208b stops on the dielectric ESL 209. Further, as described herein, where different size/width trenches are formed, this dielectric ESL 209 and selectivity reduces or eliminates problems caused by RIE lag and ARDE thereby helping to achieve common trench depths regardless of size/width for the trenches. An example for this common trench depth for different sized trenches is shown and described with respect to FIG. 4 below.

FIG. 4 is a different cross-section diagram of an example embodiment 400 associated with resulting structures in FIG. 3K. In contrast with FIG. 3K, embodiment 400 provides a cross-section view in a second direction parallel with trenches formed in the stacked structure, and this view does not pass through vias formed within the stacked structure. For the example embodiment 400, three trenches 402, 404, and 406 are shown with differing widths (e.g., W1, W2, W3). Due to the etch stop provided by the dielectric ESL 209, these trenches 402, 404, and 406 have a common depth (e.g., common target trench depth) even though they have different widths and aspect ratios. As such, the device and performance problems associated with RIE lag and ARDE problems in conventional solutions are reduced or eliminated.

It is noted that additional and/or different materials can be used for the layers described herein with respect to FIGS. 3A-3K and FIG. 4 while still taking advantage of the dielectric ESL 209 formed between the low-K layers 208a and 208b. Further, it is noted that additional low-K layers and intervening dielectric ESL layers can also be used where additional and/or different etch stops and related trench depths are desired. Other variations can also be implemented.

It is further noted that for the embodiments described herein with respect to FIGS. 3A-3K and FIG. 4, one or more process variables are preferably controlled during operation to achieve target process parameters for the processing of microelectronic workpieces as described herein. For example, one or more etch process variables, ash process variables, and/or other process variables can be controlled to achieve target process parameters. These target process parameters can include, for example, a target depth, a target chamfer angle, target critical dimensions (CD) for the vias, and/or other target process parameters.

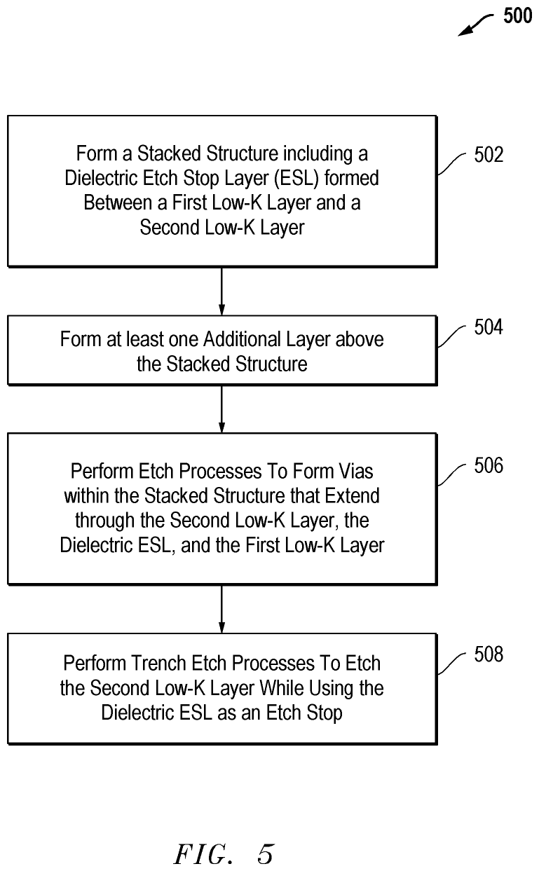

FIG. 5 is a process flow diagram of an example embodiment of a method 500 for via and trench formation that reduces RIE lag and chamfer erosion during etch processes. In block 502, a stacked structure is provided on a substrate for a microelectronic workpiece, and the stacked structure includes a dielectric etch stop layer (ESL) formed between a first low-dielectric-constant (low-K) layer and a second low-K layer. In block 504, at least one additional layer is formed above the stacked structure. In block 506, one or more etch processes are performed to open vias within the stacked structure that extend through the second low-K layer, the dielectric ESL, and the first low-K layer. In block 508, one or more trench etch processes are performed to etch the second low-K layer while using the dielectric ESL as an etch stop for the one or more trench etch processes. As described herein, by including the dielectric ESL within the stacked structure, the method 500 shown in FIG. 5 achieves common trench depths for different sized trenches, thereby reducing or eliminating problems associated with reactive ion etch (ME) lag and chamfer erosion that would occur in prior process solutions. It is further noted that additional and/or different process steps could also be used while still taking advantage of the techniques described herein.

As noted above and shown in the drawings, various embodiments of stacked structures, process steps and methods for via and trench formation are provided herein to reduce or eliminate problems, such as RIE lag and chamfer erosion, that may occur during conventional etch processes. It is noted that the process steps and methods described herein may be utilized with a wide range of processing systems including plasma processing systems. For example, the process steps and methods may be utilized with plasma etch process systems, plasma deposition process systems, or any other plasma process system. It is further noted that one or more deposition processes can be used to form the material layers described herein. For example, one or more depositions can be implemented using chemical vapor deposition (CVD), plasma enhanced CVD (PECVD), physical vapor deposition (PVD), atomic layer deposition (ALD), and/or other deposition processes. For a plasma deposition process, a precursor gas mixture can be used including but not limited to hydrocarbons, fluorocarbons, or nitrogen containing hydrocarbons in combination with one or more dilution gases (e.g., argon, nitrogen, etc.) at a variety of pressure, power, flow and temperature conditions. Lithography processes with respect to photoresist layers can be implemented using optical lithography, extreme ultra-violet (EUV) lithography, and/or other lithography processes.

The etch processes disclosed herein can be implemented using plasma etch processes, discharge etch processes, and/or other desired etch processes. For example, plasma etch processes can be implemented using plasma containing fluorocarbons, oxygen, nitrogen, hydrogen, argon, and/or other gases. In addition, operating variables for process steps can be controlled to ensure that critical dimension (CD) target parameters are achieved during via and trench formation. The operating variables may include, for example, the chamber temperature, chamber pressure, flowrates of gases, frequency and/or power applied to electrode assembly in the generation of plasma, and/or other operating variables for the processing steps. Variations can also be implemented while still taking advantage of the techniques described herein.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

“Microelectronic workpiece” as used herein generically refers to the object being processed in accordance with the invention. The microelectronic workpiece may include any material portion or structure of a device, particularly a semiconductor or other electronics device, and may, for example, be a base substrate structure, such as a semiconductor substrate or a layer on or overlying a base substrate structure such as a thin film. Thus, workpiece is not intended to be limited to any particular base structure, underlying layer or overlying layer, patterned or unpatterned, but rather, is contemplated to include any such layer or base structure, and any combination of layers and/or base structures. The description below may reference particular types of substrates, but this is for illustrative purposes only and not limitation.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate including a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

Process steps and methods for processing a microelectronic workpiece are described in various embodiments. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the described stacked structures, process steps and methods will be apparent to those skilled in the art in view of this description. It will be recognized, therefore, that the described systems and methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for via and trench formation, comprising:
forming a stacked structure on a substrate for a microelectronic workpiece, the stacked structure comprising a dielectric etch stop layer (ESL) formed between a first low-dielectric-constant (low-K) layer and a second low-K layer;
forming at least one additional layer above the stacked structure;
performing one or more etch processes to form vias within the stacked structure that extend through the second low-K layer, the dielectric ESL, and the first low-K layer; and
performing one or more trench etch processes to etch the second low-K layer while using the dielectric ESL as an etch stop for the one or more trench etch processes.

2. The method of claim 1, the one or more trench etch processes comprises a reactive ion etch (RIE) process.

3. The method of claim 2, wherein the dielectric ESL helps to reduce RIE lag associated with the RIE process as compared to process steps that do not use the dielectric ESL.

4. The method of claim 1, wherein the dielectric ESL is formed within the stacked structure at a target trench depth.

5. The method of claim 1, wherein a plurality of trenches are formed with different widths, and wherein a common depth is achieved for the trenches during the one or more trench etch processes based upon the dielectric ESL.

6. The method of claim 1, wherein the dielectric ESL protects corners of structures adjacent to the vias during the one or more trench etch processes.

7. The method of claim 6, wherein chamfer profiles for the corners are controlled by using the dielectric ESL.

8. The method of claim 1, wherein the dielectric ESL is formed within the stacked structure by depositing the dielectric ESL onto the first low-K layer

9. The method of claim 8, wherein the dielectric ESL has a thickness of less than 20 nanometers.

10. The method of claim 8, wherein the dielectric ESL has a thickness of 1 to 3 nanometers.

11. The method of claim 8, wherein the depositing the dielectric ESL on the first low-K layer comprises an atomic layer deposition (ALD) process.

12. The method of claim 1, wherein the dielectric ESL comprises at least one of AlO, AlN, SiC, SiCN, SiNCH, SiO₂, SiN, or SiON.

13. The method of claim 1, wherein the first low-K layer and the second low-K layer comprise at least one of SiCOH or SiNCH.

14. The method of claim 1, wherein the one or more trench etch processes have an etch rate (R_{LOW-K}) for the second low-K layer that is four (4) times to twenty (20) times more than an etch rate (R_{ESL}) for the dielectric ESL such that 4≤R_{LOW-K}/R_{ESL}≤20.

15. The method of claim 1, wherein the at least one additional layer comprises one or more hard mask layers formed over the second low-K layer and an organic layer formed over the one or more hard mask layers.

16. A method for via and trench formation, comprising:
forming metal regions within a layer on a substrate for a microelectronic workpiece;
forming an etch stop layer (ESL) over the metal regions;
forming a first low-dielectric-constant (low-K) layer over the ESL;
forming a dielectric ESL over the first low-K layer;
forming a second low-K layer over the dielectric ESL;
forming one or more additional layers over the second low-K layer;
performing one or more etch processes to form vias that extend through the second low-K layer, the dielectric ESL, and the first low-K layer; and
performing one or more trench etch processes including a reactive ion etch (RIE) process to etch the second low-K layer while using the dielectric ESL as an etch stop for the one or more trench etch processes.

17. The method of claim 16, wherein the dielectric ESL helps to reduce RIE lag associated with the RIE process as compared to process steps that do not use the dielectric ESL.

18. The method of claim 16, wherein a plurality of trenches are formed with different widths, and wherein a common depth is achieved for the trenches during the one or more trench etch processes based upon the dielectric ESL.

19. The method of claim 16, wherein the dielectric ESL protects corners of structures adjacent to the vias during the performing of the one or more trench etch processes, and wherein chamfer profiles for the corners are controlled by using the dielectric ESL.

20. The method of claim 16, wherein the one or more trench etch processes have an etch rate (R_{LOW-K}) for the second low-K layer that is four (4) times to twenty (20) times more than an etch rate (R_{ESL}) for the dielectric ESL such that 4≤R_{LOW-K}/R_{ESL}≤20.
